(19) United States
(12) Patent Application Publication
(10) Pub. No.: US 2025/0110827 A1
(43) Pub. Date: Apr. 3, 2025

(54) CONCURRENT READ ERROR HANDLING OPERATIONS

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 18/782,536

(22) Filed: Jul. 24, 2024

Related U.S. Application Data
(60) Provisional application No. 63/587,377, filed on Oct. 2, 2023.

(51) Int. Cl. G06F 11/10; G06F 11/07

(52) U.S. Cl. CPC G06F 11/1068; G06F 11/0763; G06F 11/1016

(57) ABSTRACT

Methods, systems, and devices for concurrent read error handling operations are described. A system may perform a read error handling procedure in which operations may be performed concurrently or in succession. For example, a second read operation may be initiated while error control is being performed for a first read operation, or while data from the first read operation is being transferred to a controller. Further, the second read operation may be terminated based on identifying one or more errors in the data from the first read operation, such that the read error handling procedure may be terminated without finishing active processes of the read error handling procedure. Additionally, the system may be configured to perform the read error handling procedure such that a channel activation operation and a channel deactivation operation may be performed at the beginning and end of the read error handling procedure, respectively.

### CROSS REFERENCE

The present Application for Patent claims priority to U.S. Patent Application No. 63/587,377 by Lien et al., entitled “CONCURRENT READ ERROR HANDLING OPERATIONS,” filed Oct. 2, 2023, which is assigned to the assignee hereof, and which is expressly incorporated by reference in its entirety herein.

### TECHNICAL FIELD

The following relates to one or more systems for memory, including concurrent read error handling operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports concurrent read error handling operations in accordance with examples as disclosed herein.

FIGS. 2A and 2B show examples of timing diagrams that support concurrent read error handling operations in accordance with examples as disclosed herein.

FIGS. 3A and 3B show examples of timing diagrams that support concurrent read error handling operations in accordance with examples as disclosed herein.

FIG. 4 shows an example of a process flow that supports concurrent read error handling operations in accordance with examples as disclosed herein.

FIG. 5 shows a block diagram of a memory system that supports concurrent read error handling operations in accordance with examples as disclosed herein.

FIGS. 6 and 7 show flowcharts illustrating a method or methods that support concurrent read error handling operations in accordance with examples as disclosed herein.

### DETAILED DESCRIPTION

A system may perform a read error handling (REH) procedure in response to identifying one or more errors as part of performing a read operation (e.g., a normal read operation). The REH procedure may include performing a series of read operations, each including reading data according to a set of parameters, transferring the data to a controller (e.g., an error control component), and performing error control on the data to determine whether one or more errors are present in the data. However, in some cases, the read operations may be performed sequentially, such that a read operation may not be performed until after a prior read operation is finished (e.g., it is determined with the prior read operation resulted in errors in the data). For example, a second read operation may not be initiated until after error control is performed for a first read operation. Because the REH procedure involves waiting for the first read operation to finish before staring the second read operation (e.g., the REH procedure does not perform the series of read operations at least partially concurrently), the REH procedure may be associated with relatively high latency. Additionally or alternatively, the system may be unable to terminate the REH procedure until after the REH procedure or until after a read operation of the REH procedure is finished, thereby increasing a risk of timeout during performing the REH procedure.

In some cases, the REH procedure may include performing, for each read operation, a channel activation operation and a channel deactivation operation on a channel associated with the respective read operation. The channel activation operation and the channel deactivation operation may be associated with reducing (e.g., draining) residual charge on the channel resulting from the read operation or a prior read operation. That is, the channel activation operation may be performed prior to performing the read operation, and the channel deactivation operation may be performed after performing the read operation. However, performing the channel activation operation and the channel deactivation operation may each be associated with relatively high power consumption and latency. Thus, performing the channel activation operation and the channel deactivation operation for each read operation of the REH procedure may cause relatively high power consumption and latency for performing the REH procedure, among other disadvantages.

In accordance with examples as described herein, a system may be configured to perform an improved REH procedure in which read operations (e.g., of the improved REH procedure) may be performed at least partially concurrently. For example, a second read operation may be initiated while error control is being performed for a first read operation (e.g., as part of the first read operation), or while data from the first read operation is being transferred to a controller (e.g., as part of the first read operation). Implementing the second read operation concurrently with performing the first read operation may decrease latency (e.g., otherwise associated with waiting for the first read operation to finish) associated with performing the improved REH procedure. Likewise, performing concurrent read operations may enable the improved REH procedure to be terminated while performing the improved REH procedure, or a read operation of the improved REH procedure, thereby decreasing a risk of timeout during performing the improved REH procedure. For example, the improved REH procedure may be terminated after performing error control (e.g., detecting or correcting one or more errors) for the first read operation, during the second read operation, such that the system may cease performing the second read operation.

Additionally or alternatively, the system may be configured to perform the improved REH procedure without a channel activation operation and/or a channel deactivation operation for every read operation of the improved REH procedure. For example, the channel activation operation and the channel deactivation operation may be performed at the beginning and end of the improved REH procedure, respectively (e.g., rather than before and after each read operation of the REH procedure). Implementing the channel activation operation and the channel deactivation operation once for the improved REH procedure may decrease power consumption and latency (e.g., otherwise associated with performing the channel activation operation and the channel deactivation operation for each read operation of the REH procedure) for performing the improved REH procedure.

Features of the disclosure are illustrated and described in the context of systems, devices, and circuits. Features of the disclosure are further illustrated and described in the context of timing diagrams, process flows, block diagrams, and flowcharts.

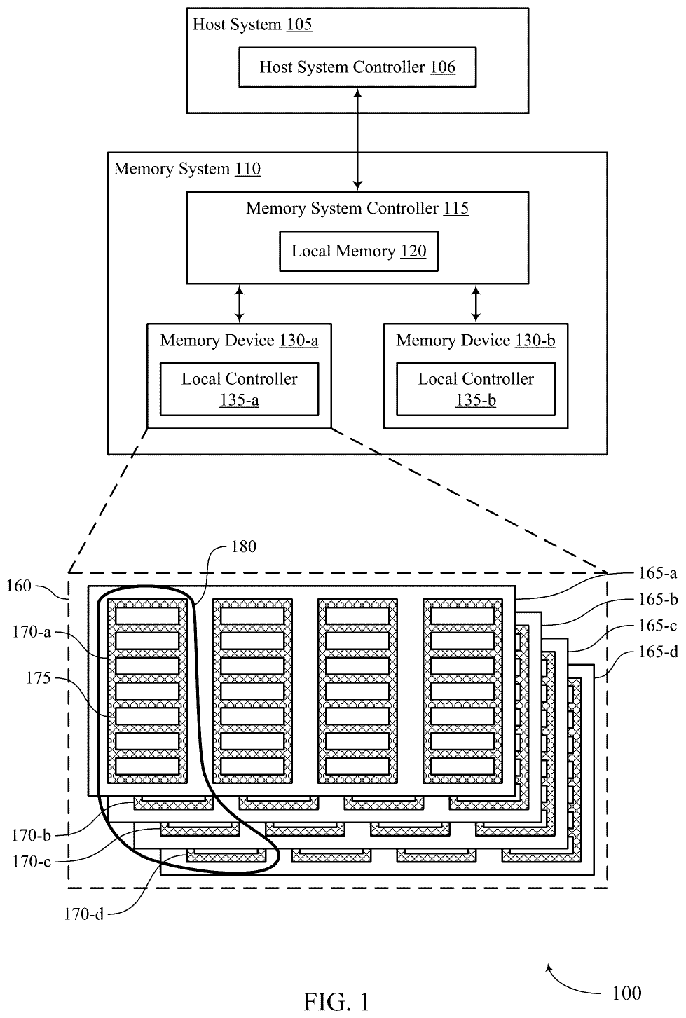

FIG. 1 shows an example of a system 100 that supports concurrent read error handling operations in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support concurrent read error handling operations. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In accordance with examples as described herein, the system 100 may be configured to perform an improved REH procedure in which read operations of the improved REH procedure may be performed at least partially concurrently. For example, a second read operation may be initiated while error control is being performed for a first read operation (e.g., as part of the first read operation), or while data from the first read operation is being transferred to a controller (e.g., as part of the first read operation). Implementing the second read operation concurrently with performing the first read operation may decrease latency (e.g., otherwise associated with waiting for the first read operation to finish) associated with performing the improved REH procedure. Likewise, performing concurrent read operations may enable the improved REH procedure to be terminated during performing the improved REH procedure, or a read operation of the improved REH procedure, thereby decreasing a risk of timeout during performing the improved REH procedure. For example, the improved REH procedure may be terminated after performing error control (e.g., detecting or correcting one or more errors) for the first read operation, during the second read operation, such that the system 100 may cease performing the second read operation.

Additionally, the system 100 may be configured to perform the improved REH procedure without a channel activation operation and a channel deactivation operation for every read operation of the improved REH procedure. For example, the channel activation operation and the channel deactivation operation may be performed at the beginning and end of the improved REH procedure, respectively (e.g., rather than before and after each read operation of the REH procedure). Implementing the channel activation operation and the channel deactivation operation once for the improved REH procedure may decrease power consumption and latency (e.g., otherwise associated with performing the channel activation operation and the channel deactivation operation for each read operation of the REH procedure) for performing the improved REH procedure.

In addition to applicability in memory systems as described herein, techniques for may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by decreasing power consumption and latency associated with performing a read error handling procedure, which may improve response times, or otherwise improve user experience, among other benefits.

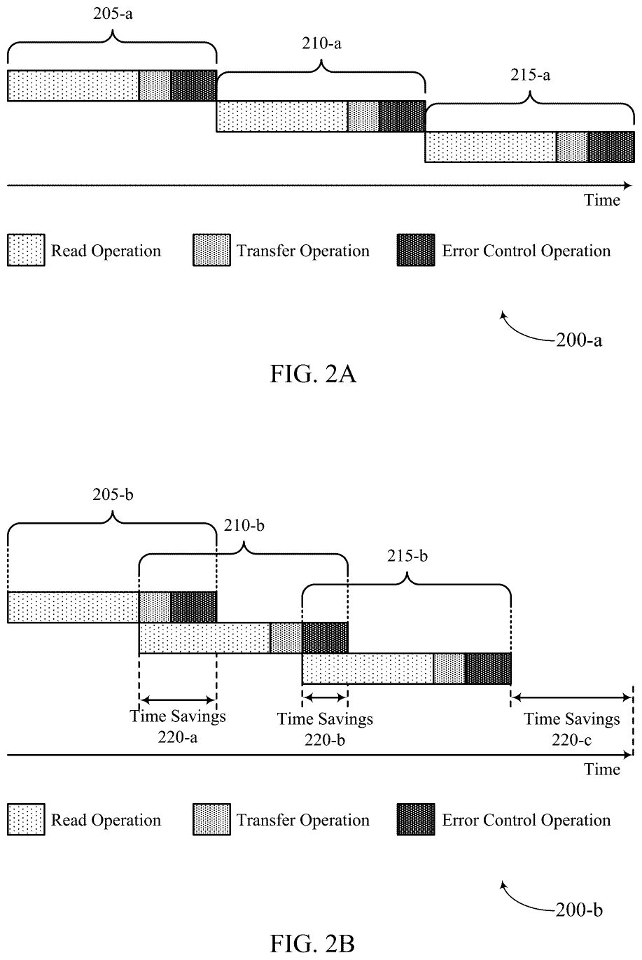

FIGS. 2A and 2B show examples of a timing diagram 200-a and a timing diagram 200-b that support concurrent read error handling operations in accordance with examples as disclosed herein. The timing diagrams 200-a and 200-b may illustrate aspects or operations of a system, which may be an example of a system 100, as described with reference to FIG. 1. For example, the timing diagrams 200-a and 200-b may illustrate operations implemented at a memory system 110, as described with reference to FIG. 1. The timing diagrams 200-a and 200-b may each illustrate a series of operations performed during respective REH procedures. For example, the timing diagram 200-a illustrates a series of operations performed during an REH procedure, in which the operations are performed sequentially and non-overlapping. Whereas, the timing diagram 200-b illustrates a series of operations performed during an improved REH procedure, in which the operations are performed at least partially concurrently.

The REH procedure or the improved REH procedure may be implemented by the system 100 based on identifying one or more errors during performing one or more read operations at the system 100. For example, the memory system 110 may perform a read operation to read data from one or more memory cells of a non-volatile memory array of the memory system 110, and the memory system 110 may determine a quantity or a rate of errors (e.g., a raw bit error rate (RBER)) identified during the read operation satisfies a threshold. Thus, the memory system 110 may implement the REH procedure of the improved REH procedure to detect and/or correct errors from the read operation, or diagnose why the quantity or the rate of errors satisfied the threshold.

The REH procedure and the improved REH procedure may each include a series of operations including read operations, transfer operations, error control operations, or any combination thereof. Each read operation may include reading data from the one or more pages of the one or more memory cells of the non-volatile memory array. In some examples, each memory cell may be a single-level cell (SLC), a multi-level cell (MLC), a triple-level cell (TLC), a quad-level cell (QLC), a penta-level cell (PLC), or another multiple-level cell. For example, a read operation for one or more TLCs may include reading data from each of the three pages of each TLC. In some cases, each read operation may be associated with different parameters (e.g., sensing level, sensing bin, sensing duration, corrective read). In some such cases, each read operation may include reading the one or more pages at a level (e.g., level 0-7) and a bin (e.g., bin 0-7) as defined by a block family error avoidance (BFEA) operation. For example, a first operation 205 may include rereading the one or more pages (e.g., BFEA+0bin), a second operation 210 may include rereading the one or more pages at another level or bin (e.g., BFEA+1bin) of the one or more memory cells, and a third operation 215 may include rereading the one or more pages at another level or bin (e.g., BFEA+2bin) of the one or more memory cells. In some such examples, 0bin may correspond to no read level shift (e.g., default read level), whereas each subsequent bin may correspond to an increased read level shift (e.g., corresponding to longer data retention and increased charge loss). In some implementations, upon reaching 7bin, a block associated with the one or more pages may be folded and data from the block may be moved to another block. Although the timing diagrams 200-a and 200-b each illustrate the respective REH procedures including three operations, it is understood that the respective REH procedures may include any quantity of operations (e.g., less than three operations, greater than three operations).

In some cases, each read operation may be ordered within the REH procedure or the improved REH procedure based on simplicity and/or latency, such that the system 100 may perform simpler and/or lower latency read operations prior to more complex and/or higher latency read operations when performing the REH procedure or the improved REH procedure. For example, the memory system 110 may perform the first operation 205 before the second operation 210 within the REH procedure and the improved REH procedure because the first operation 205 is associated with being simpler or having lower latency than the second operation 210.

The REH procedure and the improved REH procedure may include a series of transfer operations associated with transferring data to a controller (e.g., the memory system controller 115, the host system controller 106) of the system 100 after reading the data. In some cases, each transfer operation may involve transferring data read from the one or more pages during the respective read operation to the memory system controller 115. For example, the first operation 205 may include transferring data read during the first operation 205 from the one or more pages to the memory system controller 115; the second operation 210 may include transferring data read during the second operation 210 from the one or more pages to the memory system controller 115; and the third operation 215 may include transferring data read during the third operation 215 from the one or more pages to the memory system controller 115. In some implementations, the data may be transferred to the memory system controller 115 based on the memory system controller 115 including an error control component, or based on the memory system controller 115 being configured to perform error control operations for the data.

The REH procedure and the improved REH procedure may include a series of error control operations associated with detecting or correcting one or more errors in the data transferred to the controller. In some cases, each error control operation may involve decoding the data read from the one or more pages to determine whether one or more errors are present in the data. In some such cases, performing the error control operation may include determining whether a quantity of errors present in the data satisfies a threshold. For example, the first operation 205 may include determining whether a quantity of errors present in the data read during the first operation 205 satisfies the threshold; the second operation 210 may include determining whether a quantity of errors present in the data read during the second operation 210 satisfies the threshold; and the third operation 215 may include determining whether a quantity of errors present in the data read during the third operation 215 satisfies the threshold.

In some cases, the REH procedure and the improved REH procedure may be terminated based on determining the quantity of errors in data read during one of the operations satisfies the threshold. However, if the memory system 110 is implementing the REH procedure, the REH procedure may not be terminated until the REH procedure has completed all of the operations of the REH procedure. In another case, if the memory system 110 is implementing the REH procedure, the REH procedure may not be terminated until an operation of the REH procedure has completed. For example, if it is determined that the quantity of errors satisfies the threshold during the second operation 210-a, the REH procedure may not be terminated until the second operation 210-a has completed. Whereas, if the memory system 110 is implementing the improved REH procedure, the improved REH procedure may be terminated immediately once the memory system 110 has determined that the quantity of errors satisfies the threshold. For example, if it is determined that the quantity of error satisfies the threshold during the second operation 210-b, the memory system 110 may terminate the improved REH procedure, thereby ceasing to perform the second operation 210-b and any other concurrent operations of the REH procedure (e.g., the third operation 215-b). Implementing immediate termination may enable improved latency and lower bandwidth consumption due to ceasing performing the REH procedure.

The timing diagrams 200-a and 200-b each illustrate a timing for performing the first operation 205, the second operation 210, and the third operation 215, such that a length (e.g., along the time axis) of each patterned box represents a time for performing the respective operation. For example, a read operation (e.g., 90 μs) may be associated with taking relatively more time to complete than a corresponding transfer operation (e.g., 16 μs) or error control operation (e.g., 20 μs). The timing diagrams 200-a and 200-b each illustrate performing the first operation 205, the second operation 210, and the third operation 215 serially, such that the REH procedure and the improved REH procedure begin with the first operation 205, followed by the second operation 210, and succeeded by the third operation 215.

The timing diagram 200-a illustrates the REH procedure, in which each operation thereof is not initiated until a prior operation is completed. Accordingly, in the REH procedure, the second operation 210-a is not initiated until the first operation 205-a is completed, and the third operation 215-a is not initiated until the second operation 210-a is completed. For example, the read operation of the second operation 210-a is not initiated until a time at which the error control operation of the first operation 205-a is completed. However, waiting to begin each operation until a prior operation is completed may be associated with relatively high latency. Thus, performing the REH procedure as illustrated in the timing diagram 200-a may be associated with relatively high latency.

However, the timing diagram 200-b illustrates the improved REH procedure, in which each operation may be initiated at least partially concurrently with performing a prior operation. That is, in the improved REH procedure, the second operation 210-b may be initiated during performing the first operation 205-b, and the third operation 215-b may be initiated during performing the second operation 210-b. In some cases, each read operation may be initiated during (e.g., at the beginning of) the transfer operation of the prior operation, or each read operation may be initiated during (e.g., at the beginning of) the error control operation of the prior operation. For example, the read operation of the second operation 210-b may be initiated during the transfer operation of the first operation 205-b, and the read operation of the third operation 215-b may be initiated during the error control operation of the second operation 210-b. In some such cases, the read operations may be initiated concurrently with the transfer operation or the error control operation based on the transfer operation and the error control operation including different componentry of the memory system 110 than the read operations.

Performing concurrent operations of the improved REH procedure may reduce latency otherwise associated with waiting to perform each operation until a prior operation is completed (e.g., as in previous implementations). For example, initiating the second operation 210-b concurrently with performing the transfer operation of the first operation 205-b may yield time savings 220-a. Likewise, initiating the third operation 215-b concurrently with performing the error control operation of the first operation 205-b may yield time savings 220-b. Thus, performing the second operation 210-b concurrently with the first operation 205-b, and performing the third operation 215-b concurrently with the second operation 210-b may yield total time savings 220-c, compared to the timing diagram 200-a. Thus, performing the improved REH procedure as illustrated in the timing diagram 200-b may be associated with relatively low latency.

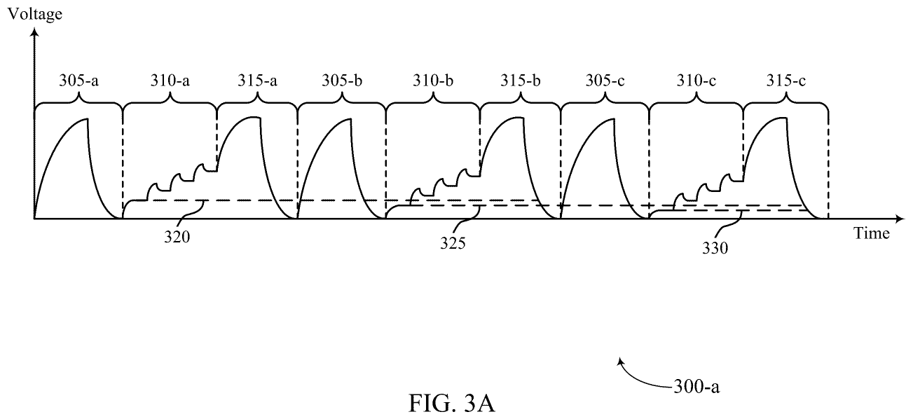

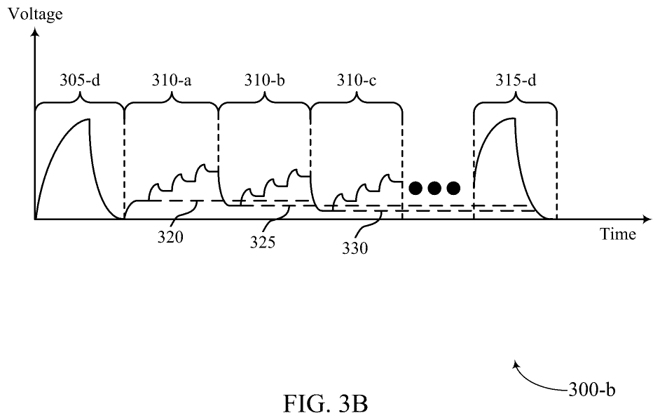

FIGS. 3A and 3B show examples of a timing diagram 300-a and a timing diagram 300-b that support concurrent read error handling operations in accordance with examples as disclosed herein. The timing diagrams 200-a and 200-b may illustrate aspects or operations of a system, which may be an example of a system 100, as described with reference to FIG. 1. For example, the timing diagram 200-a and 200-b may illustrate operations implemented at a memory system 110, as described with reference to FIG. 1. The timing diagrams 300-a and 300-b may each illustrate a timing and voltage of a series of operations performed during respective REH procedures. For example, the timing diagram 300-a illustrates a series of operations performed during an REH procedure, in which each operation is preceded and succeeded by a channel activation operation and a channel deactivation operation, respectively. Whereas, the timing diagram 300-b illustrates a series of operations performed during an improved REH procedure, in which the channel activation operation and the channel deactivation operation are performed at the beginning and end of the improved REH procedure.

The timing diagrams 300-a and 300-b each illustrate timings and voltages associated with operations of respective REH procedures. The timing diagrams 300-a and 300-b illustrate the respective REH procedures each including a first read operation 310-a, a second read operation 310-b, and a third read operation 310-c. Each read operation may be an example of a read operation as part of a respective operation, such as a first operation 205, a second operation 210, and a third operation 215, as described with reference to FIGS. 2A and 2B. For example, the first read operation 310-a may be an example of the read operation of the first operation 205.

Each read operation may include reading data from one or more pages of one or more memory cells of a non-volatile memory array. In some cases, the one or more memory cells may be SLCs, MLCs, TLCs, QLCs, PLCs, or other multiple level cells. The timing diagrams 300-a and 300-b illustrate the voltage on a channel associated with the one or more memory cells during reading the data from the one or more pages of the one or more memory cells. For example, the timing diagrams 300-a and 300-b illustrate, for each read operation, the voltage of reading 4 pages of the one or more memory cells, where the voltage may increase in steps (e.g., step up) for each page read. In some implementations, the voltage may rapidly ramp up then subsequently fall to a sensing voltage for each page. In some cases, each read operation may be associated with different parameters (e.g., sensing level, sensing bin, sensing duration, corrective read). For example, the first read operation 310-a may include reading the pages without adjusting the parameters (e.g., rereading) such that the pages are read at an initial level or bin 320 (e.g., BFEA+0bin) of the one or more memory cells, the second read operation 310-b may include reading the pages at another level or bin 325 (e.g., BFEA+1bin) of the one or more memory cells, and the third read operation 310-c may include reading the pages at another level or bin 330 (e.g., BFEA+2bin) of the one or more memory cells.

The timing diagrams 300-a and 300-b also illustrate channel activation operations 305 and channel deactivation operations 315. The channel activation operations 305 and the channel deactivation operations 315 may each include applying a relatively high voltage then dropping the relatively high voltage, and may be applied to decrease (e.g., reduce, drain) a residual charge on the channel. For example, the channel activation operation 305 may be applied to drain the residual charge on the channel from any previous operations involving applying a voltage to the channel. Likewise, the channel deactivation operation 315 may be applied to drain the residual charge on the channel from the one or more read operations applied during the respective REH procedures. In some cases, decreasing the residual charge on the channel may increase access accuracy (e.g., sensing accuracy) during performing future operations (e.g., read operations) on the channel. For example, decreasing the residual charge on the channel may prevent read disturbance due to hot carrier injection.

The timing diagram 300-a illustrates the REH procedure, in which the channel activation operation 305 and the channel deactivation operation 315 are applied before and after each read operation of the REH procedure, respectively. For example, the channel activation operation 305-a may be applied before the first read operation 310-a, and the channel deactivation operation 315-a may be applied after the first read operation 310-a. Likewise, the channel activation operation 305-b may be applied before the second read operation 310-b, and the channel deactivation operation 315-b may be applied after the second read operation 310-b. Further, the channel activation operation 305-c may be applied before the third read operation 310-c, and the channel deactivation operation 315-c may be applied after the third read operation 310-c. In some cases, the channel activation operation 305 (e.g., the channel activation operation 305-b) may be immediately subsequent to the channel deactivation operation 315 (e.g., the channel deactivation operation 315-a) of the prior read operation. In some cases, the channel deactivation operation 315 (e.g., the channel deactivation operation 315-a) may function as a channel activation operation 305 (e.g., the channel activation operation 305-b) for a succeeding read operation. However, applying the channel activation operation 305 or the channel deactivation operation 315 may be associated with relatively high latency and high power consumption. Thus, applying the channel activation operation 305 and the channel deactivation operation 315 for each read operation of the REH procedure may result in the REH procedure having relatively high latency and high power consumption.

The timing diagram 300-b illustrates the improved REH procedure, in which the channel activation operation 305 and the channel deactivation operation 315 are applied at the beginning and the end of the improved REH procedure, respectively. For example, the channel activation operation 305-d may be applied before the first read operation 310-a, and the channel deactivation operation 315-d may be applied after the third read operation 310-c. In some cases, if the third read operation 310-c does not yield a completion of the improved REH procedure, then the channel deactivation operation 315-d may not be performed until the improved REH procedure is completed. Applying the channel activation operation 305 and the channel deactivation operation 315 at the beginning and the end of the improved REH procedure may be associated with relatively low latency and low power consumption, thereby result in the improved REH procedure having relatively low latency and low power consumption.

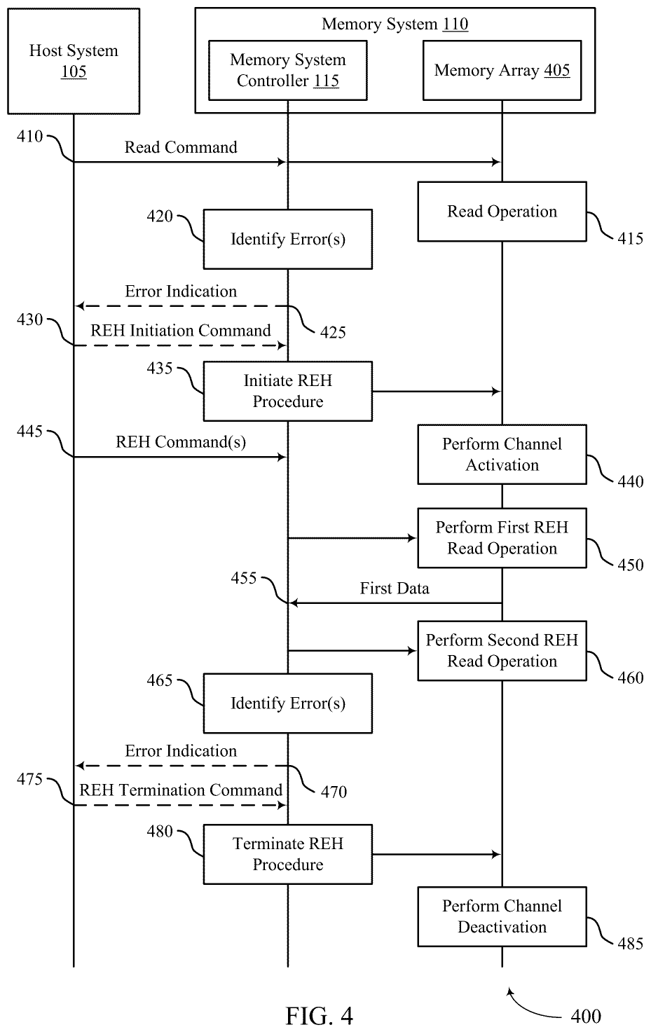

FIG. 4 shows an example of a process flow 400 that supports concurrent read error handling operations in accordance with examples as disclosed herein. The process flow 400 may illustrate aspects or operations of a system, which may be an example of a system 100, as described with reference to FIG. 1. For example, the process flow 400 may be implemented by a host system 105 and a memory system 110, which may include at least a memory system controller 115, as described with reference to FIG. 1. The memory system 110 may also include a memory array 405, which may be a non-volatile memory array including a quantity of non-volatile memory cells. For example, the memory array 405 may be a NAND memory array, a resistive RAM (ReRAM) array, or a phase-change RAM (PCRAM) array, among other examples.

In the following description of the process flow 400, the methods, techniques, processes, and operations may be performed in different orders or at different times. Further, some operations may be left out of the process flow 400, or other operations may be added to the process flow 400. Aspect of the process flow 400 illustrated at the host system 105 may be implemented by one or more processors or a host system controller 106 of the host system 105, as described with reference to FIG. 1. Additionally, or alternatively, aspects of the process flow 400 may be implemented as instructions stored in memory (e.g., firmware). For example, the instructions, if executed by a controller (e.g., the memory system controller 115, the host system controller 106), may cause the controller to perform the operations of the process flow 400. The process flow 400 may depict operations for performing an improved REH procedure, in which operations of the improved REH procedure may be performed concurrently to reduce latency.

At 410, the host system 105 may transmit a read command to the memory system 110. The memory system controller 115 may receive the read command (e.g., on behalf of the memory system 110) and issue the read command to the memory array 405. In some cases, the read command may indicate the memory system 110 to perform a read operation for data stored in the memory array 405. In some cases, the read command may include an indication that the memory system is to use REH procedures that include performing read retries and other read operation that at least partially overlap in time. In some cases, the read command may use an op code that indicates to use the REH procedures that include performing read retries and other read operation that at least partially overlap in time. In some cases, the op code for this read operation may be different than an op code used for read operations that utilize different REH procedures.

At 415, the read operation may be performed at the memory array 405. The read operation may be performed in accordance with the read command received from the host system 105 at step 410 of the process flow 400. For example, the read operation may read data from an address of the memory array 405 indicated by the read command. In some cases, performing the read operation may include sensing the data from the memory array 405 and transferring the data from the memory array 405 to the memory system controller 115.

At 420, the memory system controller 115 may identify one or more errors in the data. For example, the memory system controller 115, or an error control component of the memory system controller 115, may perform an error control operation on the data read from the memory array 405 at step 415 of the process flow 400. The memory system controller 115 may identify a quantity of errors in the data, or a rate of errors in the data, and determine whether the quantity of errors or the rate of errors satisfies a threshold. In some cases, the process flow 400 may continue to step 425 based on determining the quantity of errors or the rate of errors satisfies the threshold, otherwise the process flow 400 may restart at step 410.

At 425, the memory system controller 115 may transmit an error indication. The error indication may be received at the host system 105, and may indicate that the quantity of errors in the data or the rate of errors in the data identified at step 420 of the process flow 400 satisfies the threshold.

At 430, the host system 105 may transmit an REH initiation command. The REH initiation command may be received at the memory system controller 115, and may indicate the memory system 110 to initiate an REH procedure. In some examples, the REH initiation command may indicate to perform the REH procedure on the memory array 405, based on receiving the error indication at step 425 of the process flow 400.

At 435, the memory system controller 115 may initiate the REH procedure. In some cases, the memory system controller 115 may initiate the REH procedure on the memory array 405 based on receiving the REH initiation command (e.g., the REH initiation command indicating the memory array 405). Initiating the REH procedure may include transmitting a command to the memory array 405 to perform a channel activation operation on a channel associated with one or more memory cells of the memory array 405 (e.g., targeted by the REH procedure).

At 440, the channel activation operation may be performed at the memory array 405. The channel activation operation may be performed on the channel associated with the one or more memory cells of the memory array 405 targeted by the REH procedure. The channel activation operation may reduce (e.g., drain) a residual charge on the channel from performing prior access operations. In some cases, the one or more memory cells may be targeted by the REH procedure based on identifying that the one or more memory cells stored the data that was identified at step 420 of the process flow 400 to have had the quantity of errors or the rate of errors that satisfied the threshold.

At 445, the host system 105 may send one or more REH commands to the memory system controller 115. Each REH command may indicate the memory system 110 to perform one operation of the REH procedure. For example, a first REH command may indicate the memory system 110 to perform a first operation of the REH procedure, which may be an example of the first operation 205-b, as described with reference to FIG. 2B. In some cases, the host system 105 may send all the REH commands for all the operations of the REH procedure serially during step 445 of the process flow 400, such that all the REH commands may be received with a duration. However, in other cases, the host system 105 may send each REH command for each operation of the REH procedure immediately before the respective operation is to be performed. In some examples, step 445 may be concurrent with steps 435 through 465 of the process flow 400. For example, the memory system controller 115 may receive the first REH command during performing the channel activation operation at step 440 of the process flow, and the memory system controller 115 may receive a second REH command during performing the first operation of the REH procedure.

At step 450, a first REH read operation may be performed at the memory array 405. In some cases, the first REH read operation may be an example of a first read operation 310-a, as described with reference to FIG. 3B. The first REH read operation may include reading data from one or more pages of the one or more memory cells. In some cases, the first REH read operation may be initiated based on receiving a command for the first REH read operation from the host system 105, which may be received at the memory system controller 115 and issued to the memory array 405. In some examples, the first REH read operation may include rereading the data that was identified at step 420 of the process flow 400 to have had the quantity of errors or the rate of errors that satisfied the threshold. In some implementations, the REH procedure may be ordered by simplicity and latency such that the first REH read operation may be performed first in the order of the REH procedure based on the first REH read operation being the simplest or lowest latency operation of the REH procedure.

At step 455, the memory array 405 may transfer first data read during the first REH read operation to the memory system controller 115. For example, the first data read from the memory array 405 as part of the first REH read operation may be transmitted to the memory system controller 115 based on finishing reading the first data.

At step 460, a second REH read operation may be performed at the memory array 405. In some cases, the second REH read operation may be an example of a second read operation 310-b, as described with reference to FIG. 3B. The second REH read operation may include reading data from the one or more pages of at a different level or bin of the one or more memory cells, or from one or more other pages of the one or more memory cells, or a combination thereof. In some cases, the second REH read operation may be initiated based on receiving a command for the second REH read operation from the host system 105, which may be received at the memory system controller 115 and issued to the memory array 405. For example, the command for the second REH read operation may be received from the host system 105 during performing the first REH read operation at step 450 of the process flow 400. In some cases, the second REH read operation may be performed concurrently with transferring the first data from the memory array 405 to the memory system controller 115, such that the second REH read operation may be initiated immediately after finishing the first REH read operation. In some implementations, the second REH read operation may be performed second in the order of the REH procedure based on the second REH read operation being relatively more complex or having relatively higher latency than the first REH read operation.

At step 465, the memory system controller 115 may identify one or more errors in the first data. For example, the memory system controller 115, or an error control component of the memory system controller 115, may perform an error control operation on the first data transferred from the memory array 405 at step 455 of the process flow 400. As part of the error control operation, the memory system controller 115 may identify a quantity of errors in the data, or a rate of errors in the data, and determine whether the quantity of errors or the rate of errors satisfies a threshold. In some cases, the process flow 400 may continue to step 470 based on determining that the quantity of errors or the rate of errors satisfies the threshold, otherwise the process flow 400 may finish the second REH read operation and follow similar steps as described with reference to the first REH read operation (e.g., transferring second data to the memory system controller 115, performing error control on the second data).

In some cases, the error control operation may be performed concurrently with the second REH read operation. For example, the second REH read operation may be initiated during transferring the first data to the memory system controller 115, such that the error control operation may be initiated during performing the second REH read operation. In other examples, the second REH read operation may be initiated during the error control operation. In either example, the error control operation may determine that the quantity of errors or the rate of errors satisfies the threshold during performing the second REH read operation.

At 470, the memory system controller 115 may transmit an error indication. The error indication may be received at the host system 105, and may indicate that the quantity of errors in the first data or the rate of errors in the first data identified at step 465 of the process flow 400 satisfies the threshold.

At 475, the host system 105 may transmit an REH termination command. The REH termination command may be received at the memory system controller 115, and may indicate the memory system 110 to terminate the REH procedure, based on receiving the error indication at step 470 of the process flow 400.

At 480, the memory system controller 115 may terminate the REH procedure. In some cases, the memory system controller 115 may terminate the REH procedure on the memory array 405 based on receiving the REH termination command. In some examples, terminating the REH procedure may include transmitting a command to the memory array 405 to cease performing the second REH read operation. For example, the steps 465 through 475 of the process flow 400 may be performed concurrently with performing the second REH read operation. After transmitting the command to cease performing the second REH read operation, the second REH read operation may be terminated, such that any active processes associated with the second REH read operation may be stopped (e.g., reading second data associated with the second REH read operation, transferring the second data, performing error control for the second data). In some examples, terminating the REH procedure may include transmitting a command to the memory array 405 to perform a channel deactivation operation on the channel.

At 485, the channel activation operation may be performed at the memory array 405. The channel deactivation operation may be performed on the channel associated with the one or more memory cells, based on receiving the command to perform the channel deactivation operation. The channel deactivation operation may reduce (e.g., drain) the residual charge on the channel from performing the REH procedure.

In accordance with examples as described herein, the improved REH procedure may decrease latency and power consumption (e.g., otherwise associated with performing a prior implementation of a REH procedure). For example, the operations of the REH procedure may be performed concurrently, and the channel activation operation and the channel deactivation operation are not performed for every operation, thereby reducing latency for performing the REH procedure. Likewise, refraining from performing the channel activation operation and the channel deactivation operation for every operation of the REH procedure may reduce power consumption for performing the REH procedure, among other advantages.

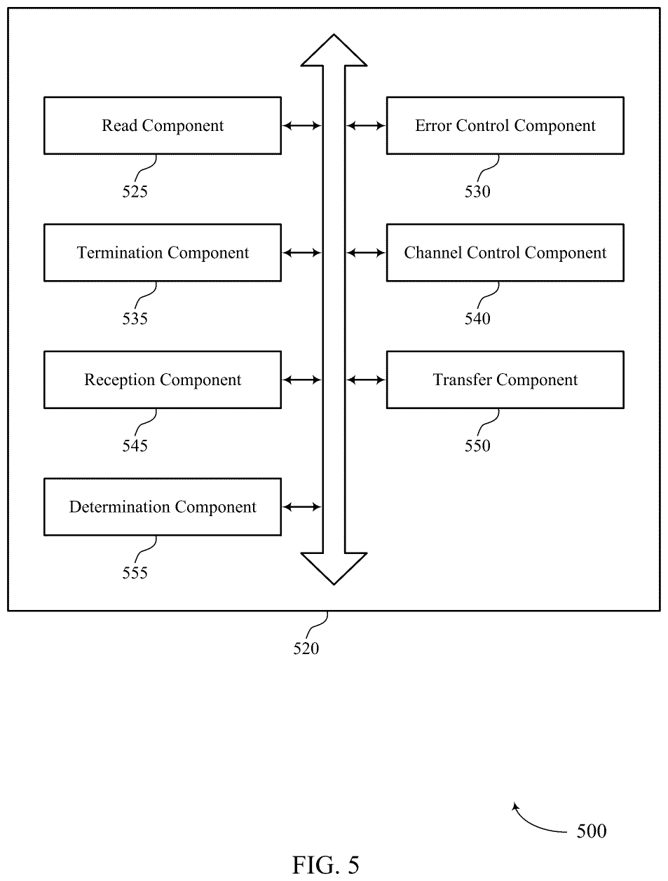

FIG. 5 shows a block diagram 500 of a memory system 520 that supports concurrent read error handling operations in accordance with examples as disclosed herein. The memory system 520 may be an example of aspects of a memory system as described with reference to FIGS. 1 through 4. The memory system 520, or various components thereof, may be an example of means for performing various aspects of concurrent read error handling operations as described herein. For example, the memory system 520 may include a read component 525, an error control component 530, a termination component 535, a channel control component 540, a reception component 545, a transfer component 550, a determination component 555, or any combination thereof. Each of these components, or components of subcomponents thereof (e.g., one or more processors, one or more memories), may communicate, directly or indirectly, with one another (e.g., via one or more buses).

The read component 525 may be configured as or otherwise support a means for performing a first read operation as part of a read error handling procedure of a memory system. The error control component 530 may be configured as or otherwise support a means for performing an error correction operation on data associated with the first read operation based at least in part on performing the first read operation. In some examples, the read component 525 may be configured as or otherwise support a means for performing a second read operation as part of the read error handling procedure based at least in part on performing the first read operation, where the second read operation is initiated before the error correction operation is complete. The termination component 535 may be configured as or otherwise support a means for terminating the read error handling procedure based at least in part on identifying that the error correction operation successfully corrected one or more errors in the data after initiating the performance of the second read operation.

In some examples, the channel control component 540 may be configured as or otherwise support a means for performing a channel activation operation to reduce residual charge on a channel associated with the read error handling procedure, where performing the first read operation is based at least in part on performing the channel activation operation. In some examples, the channel control component 540 may be configured as or otherwise support a means for performing a channel deactivation operation to reduce the residual charge on the channel based at least in part on terminating the read error handling procedure.

In some examples, the reception component 545 may be configured as or otherwise support a means for receiving a first command for the first read operation, where performing the first read operation is based at least in part on receiving the first command. In some examples, the reception component 545 may be configured as or otherwise support a means for receiving a second command for the second read operation, where performing the second read operation is based at least in part on receiving the second command concurrently with performing the first read operation or the error correction operation.

In some examples, to support terminating the read error handling procedure, the read component 525 may be configured as or otherwise support a means for ceasing to perform the second read operation before completing the second read operation.

In some examples, the reception component 545 may be configured as or otherwise support a means for receiving a command to terminate the read error handling procedure based at least in part on identifying that the error correction operation successfully corrected the one or more errors in the data, where ceasing to perform the second read operation is based at least in part on receiving the command.

In some examples, the transfer component 550 may be configured as or otherwise support a means for transferring the data from a non-volatile memory array of the memory system to a controller of the memory system based at least in part on performing the first read operation, where the error correction operation is performed at the controller based at least in part on transferring the data.

In some examples, the second read operation is performed after the first read operation based at least in part on the first read operation being associated with lower latency or more simplicity than the second read operation.

In some examples, performing the first read operation includes reading one or more first pages of a non-volatile memory array, and performing the second read operation includes reading one or more second pages at a different level of the non-volatile memory array.

In some examples, the one or more first pages and the one or more second pages are associated with single-level cells, multi-level cells, triple-level cells, quad-level cells, or penta-level cells.

In some examples, the read component 525 may be configured as or otherwise support a means for performing a third read operation as part of a second read error handling procedure of the memory system. In some examples, the error control component 530 may be configured as or otherwise support a means for performing a second error correction operation on second data associated with the third read operation based at least in part on performing the third read operation. In some examples, the read component 525 may be configured as or otherwise support a means for performing a fourth read operation as part of the second read error handling procedure based at least in part on performing the third read operation, where the fourth read operation is initiated before the second error correction operation is complete. In some examples, the error control component 530 may be configured as or otherwise support a means for performing a third error correction operation on third data associated with the fourth read operation based at least in part on performing the fourth read operation. In some examples, the read component 525 may be configured as or otherwise support a means for performing a fifth read operation as part of the second read error handling procedure based at least in part on performing the fourth read operation, where the fifth read operation is initiated before the third error correction operation is complete. In some examples, the termination component 535 may be configured as or otherwise support a means for terminating the second read error handling procedure based at least in part on identifying that the third error correction operation successfully corrected one or more errors in the third data after initiating the performance of the fifth read operation.

In some examples, the read component 525 may be configured as or otherwise support a means for performing a third read operation. In some examples, the determination component 555 may be configured as or otherwise support a means for determining whether a rate of errors or a quantity of errors satisfies a threshold. In some examples, the read component 525 may be configured as or otherwise support a means for initiating the read error handling procedure based at least in part on determining that the rate of errors or the quantity of errors satisfies the threshold, where the performing the first read operation is based at least in part on initiating the read error handling procedure.

In some examples, the reception component 545 may be configured as or otherwise support a means for receiving a plurality of operation commands based at least in part on initiating the read error handling procedure, where the plurality of operation commands include at least a first command for the first read operation and a second command for the second read operation.

The channel control component 540 may be configured as or otherwise support a means for performing a channel activation operation to reduce residual charge on a channel. In some examples, the read component 525 may be configured as or otherwise support a means for performing a first operation as part of a read error handling procedure. In some examples, the read component 525 may be configured as or otherwise support a means for performing a second operation as part of the read error handling procedure at least partially concurrently with performing the first operation. In some examples, the termination component 535 may be configured as or otherwise support a means for terminating the read error handling procedure based at least in part on identifying one or more errors in data stored in memory cells associated with the channel during performing the second operation. In some examples, the channel control component 540 may be configured as or otherwise support a means for performing a channel deactivation operation to reduce the residual charge on the channel based at least in part on terminating the read error handling procedure.

In some examples, the reception component 545 may be configured as or otherwise support a means for receiving a first command for the first operation, where performing the first operation is based at least in part on receiving the first command. In some examples, the reception component 545 may be configured as or otherwise support a means for receiving a second command for the second operation, where performing the second operation is based at least in part on receiving the second command concurrently with performing the first operation.

In some examples, to support terminating the read error handling procedure, the read component 525 may be configured as or otherwise support a means for ceasing to perform the second operation before completing the second operation.

In some examples, the reception component 545 may be configured as or otherwise support a means for receiving a command to terminate the read error handling procedure based at least in part on identifying the one or more errors in the data, where ceasing to perform the second operation is based at least in part on receiving the command.

In some examples, the first operation includes a first read operation for the data and a first error correction operation for the data. In some examples, the second operation includes a second read operation for the data stored in the memory cells and a second error correction operation for the data.

In some examples, transferring the data from a non-volatile memory array of a memory system to a controller of the memory system based at least in part on performing the first read operation, where the first error correction operation is performed at the controller based at least in part on transferring the data.

In some examples, performing the first read operation includes reading one or more first pages of a non-volatile memory array, and performing the second read operation includes reading one or more second pages at a different level of the non-volatile memory array.

In some examples, the one or more first pages and the one or more second pages are associated with single-level cells, multi-level cells, triple-level cells, quad-level cells, or penta-level cells.

In some examples, the second operation is performed after the first operation based at least in part on the first operation being associated with lower latency or more simplicity than the second operation.

In some examples, the channel control component 540 may be configured as or otherwise support a means for performing a second channel activation operation to reduce residual charge on a second channel. In some examples, the read component 525 may be configured as or otherwise support a means for performing a third operation as part of a second read error handling procedure. In some examples, the read component 525 may be configured as or otherwise support a means for performing a fourth operation as part of the second read error handling procedure at least partially concurrently with performing the third operation. In some examples, the read component 525 may be configured as or otherwise support a means for performing a fifth operation as part of the second read error handling procedure at least partially concurrently with performing the fourth operation. In some examples, the termination component 535 may be configured as or otherwise support a means for terminating the second read error handling procedure based at least in part on identifying one or more second errors in second data stored in second memory cells associated with the second channel during performing the fifth operation. In some examples, the channel control component 540 may be configured as or otherwise support a means for performing a second channel deactivation operation to reduce the residual charge on the second channel based at least in part on terminating the second read error handling procedure.

In some examples, the read component 525 may be configured as or otherwise support a means for performing a read operation. In some examples, the determination component 555 may be configured as or otherwise support a means for determining whether a rate of errors or a quantity of errors satisfies a threshold. In some examples, the read component 525 may be configured as or otherwise support a means for initiating the read error handling procedure based at least in part on determining that the rate of errors or the quantity of errors satisfies the threshold, where performing the first operation is based at least in part on initiating the read error handling procedure.

In some examples, the reception component 545 may be configured as or otherwise support a means for receiving a plurality of operation commands based at least in part on initiating the read error handling procedure, where the plurality of operation commands include at least a first command for the first operation and a second command for the second operation.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

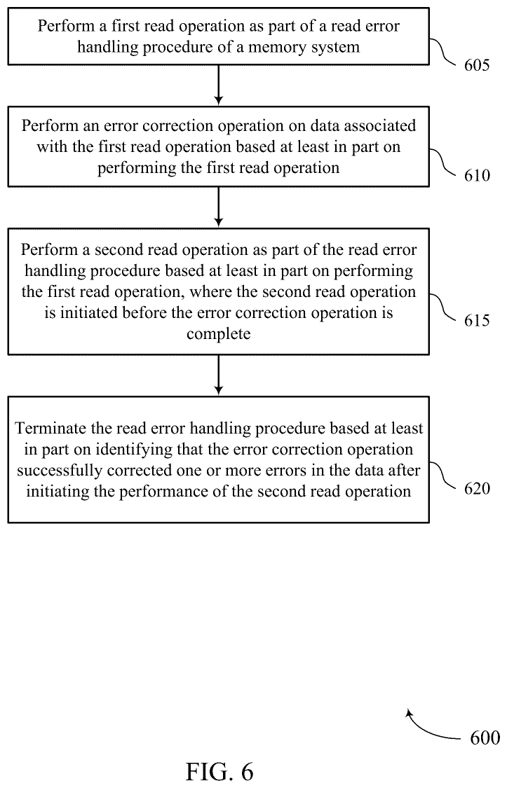

FIG. 6 shows a flowchart illustrating a method 600 that supports concurrent read error handling operations in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include performing a first read operation as part of a read error handling procedure of a memory system. In some examples, aspects of the operations of 605 may be performed by a read component 525 as described with reference to FIG. 5.

At 610, the method may include performing an error correction operation on data associated with the first read operation based at least in part on performing the first read operation. In some examples, aspects of the operations of 610 may be performed by an error control component 530 as described with reference to FIG. 5.

At 615, the method may include performing a second read operation as part of the read error handling procedure based at least in part on performing the first read operation, where the second read operation is initiated before the error correction operation is complete. In some examples, aspects of the operations of 615 may be performed by a read component 525 as described with reference to FIG. 5.

At 620, the method may include terminating the read error handling procedure based at least in part on identifying that the error correction operation successfully corrected one or more errors in the data after initiating the performance of the second read operation. In some examples, aspects of the operations of 620 may be performed by a termination component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for performing a first read operation as part of a read error handling procedure of a memory system; performing an error correction operation on data associated with the first read operation based at least in part on performing the first read operation; performing a second read operation as part of the read error handling procedure based at least in part on performing the first read operation, where the second read operation is initiated before the error correction operation is complete; and terminating the read error handling procedure based at least in part on identifying that the error correction operation successfully corrected one or more errors in the data after initiating the performance of the second read operation.

Aspect 2: The method, apparatus, or non-transitory computer-readable medium of aspect 1, further including operations, features, circuitry, logic, means, or instructions, or any combination thereof for performing a channel activation operation to reduce residual charge on a channel associated with the read error handling procedure, where performing the first read operation is based at least in part on performing the channel activation operation and performing a channel deactivation operation to reduce the residual charge on the channel based at least in part on terminating the read error handling procedure.

Aspect 3: The method, apparatus, or non-transitory computer-readable medium of any of aspects 1 through 2, further including operations, features, circuitry, logic, means, or instructions, or any combination thereof for receiving a first command for the first read operation, where performing the first read operation is based at least in part on receiving the first command and receiving a second command for the second read operation, where performing the second read operation is based at least in part on receiving the second command concurrently with performing the first read operation or the error correction operation.

Aspect 4: The method, apparatus, or non-transitory computer-readable medium of any of aspects 1 through 3, where terminating the read error handling procedure includes operations, features, circuitry, logic, means, or instructions, or any combination thereof for ceasing to perform the second read operation before completing the second read operation.

Aspect 5: The method, apparatus, or non-transitory computer-readable medium of aspect 4, further including operations, features, circuitry, logic, means, or instructions, or any combination thereof for receiving a command to terminate the read error handling procedure based at least in part on identifying that the error correction operation successfully corrected the one or more errors in the data, where ceasing to perform the second read operation is based at least in part on receiving the command.

Aspect 6: The method, apparatus, or non-transitory computer-readable medium of any of aspects 1 through 5, further including operations, features, circuitry, logic, means, or instructions, or any combination thereof for transferring the data from a non-volatile memory array of the memory system to a controller of the memory system based at least in part on performing the first read operation, where the error correction operation is performed at the controller based at least in part on transferring the data.

Aspect 7: The method, apparatus, or non-transitory computer-readable medium of any of aspects 1 through 6, where the second read operation is performed after the first read operation based at least in part on the first read operation being associated with lower latency or more simplicity than the second read operation.

Aspect 8: The method, apparatus, or non-transitory computer-readable medium of any of aspects 1 through 7, where performing the first read operation includes reading one or more first pages of a non-volatile memory array, and performing the second read operation includes reading one or more second pages at a different level of the non-volatile memory array.

Aspect 9: The method, apparatus, or non-transitory computer-readable medium of aspect 8, where the one or more first pages and the one or more second pages are associated with single-level cells, multi-level cells, triple-level cells, quad-level cells, or penta-level cells.

Aspect 10: The method, apparatus, or non-transitory computer-readable medium of any of aspects 1 through 9, further including operations, features, circuitry, logic, means, or instructions, or any combination thereof for performing a third read operation as part of a second read error handling procedure of the memory system; performing a second error correction operation on second data associated with the third read operation based at least in part on performing the third read operation; performing a fourth read operation as part of the second read error handling procedure based at least in part on performing the third read operation, where the fourth read operation is initiated before the second error correction operation is complete; performing a third error correction operation on third data associated with the fourth read operation based at least in part on performing the fourth read operation; performing a fifth read operation as part of the second read error handling procedure based at least in part on performing the fourth read operation, where the fifth read operation is initiated before the third error correction operation is complete; and terminating the second read error handling procedure based at least in part on identifying that the third error correction operation successfully corrected one or more errors in the third data after initiating the performance of the fifth read operation.

Aspect 11: The method, apparatus, or non-transitory computer-readable medium of any of aspects 1 through 10, further including operations, features, circuitry, logic, means, or instructions, or any combination thereof for performing a third read operation; determining whether a rate of errors or a quantity of errors satisfies a threshold; and initiating the read error handling procedure based at least in part on determining that the rate of errors or the quantity of errors satisfies the threshold, where the performing the first read operation is based at least in part on initiating the read error handling procedure.

Aspect 12: The method, apparatus, or non-transitory computer-readable medium of aspect 11, further including operations, features, circuitry, logic, means, or instructions, or any combination thereof for receiving a plurality of operation commands based at least in part on initiating the read error handling procedure, where the plurality of operation commands include at least a first command for the first read operation and a second command for the second read operation.

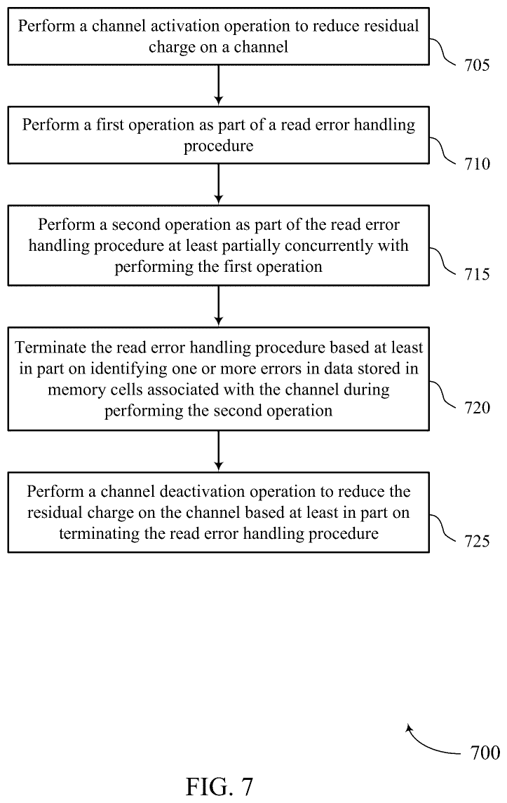

FIG. 7 shows a flowchart illustrating a method 700 that supports concurrent read error handling operations in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include performing a channel activation operation to reduce residual charge on a channel. In some examples, aspects of the operations of 705 may be performed by a channel control component 540 as described with reference to FIG. 5.

At 710, the method may include performing a first operation as part of a read error handling procedure. In some examples, aspects of the operations of 710 may be performed by a read component 525 as described with reference to FIG. 5.

At 715, the method may include performing a second operation as part of the read error handling procedure at least partially concurrently with performing the first operation. In some examples, aspects of the operations of 715 may be performed by a read component 525 as described with reference to FIG. 5.

At 720, the method may include terminating the read error handling procedure based at least in part on identifying one or more errors in data stored in memory cells associated with the channel during performing the second operation. In some examples, aspects of the operations of 720 may be performed by a termination component 535 as described with reference to FIG. 5.

At 725, the method may include performing a channel deactivation operation to reduce the residual charge on the channel based at least in part on terminating the read error handling procedure. In some examples, aspects of the operations of 725 may be performed by a channel control component 540 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 13: A method, apparatus, or non-transitory computer-readable medium including operations, features, circuitry, logic, means, or instructions, or any combination thereof for performing a channel activation operation to reduce residual charge on a channel; performing a first operation as part of a read error handling procedure; performing a second operation as part of the read error handling procedure at least partially concurrently with performing the first operation; terminating the read error handling procedure based at least in part on identifying one or more errors in data stored in memory cells associated with the channel during performing the second operation; and performing a channel deactivation operation to reduce the residual charge on the channel based at least in part on terminating the read error handling procedure.

Aspect 14: The method, apparatus, or non-transitory computer-readable medium of aspect 13, further including operations, features, circuitry, logic, means, or instructions, or any combination thereof for receiving a first command for the first operation, where performing the first operation is based at least in part on receiving the first command and receiving a second command for the second operation, where performing the second operation is based at least in part on receiving the second command concurrently with performing the first operation.

Aspect 15: The method, apparatus, or non-transitory computer-readable medium of any of aspects 13 through 14, where terminating the read error handling procedure includes operations, features, circuitry, logic, means, or instructions, or any combination thereof for ceasing to perform the second operation before completing the second operation.

Aspect 16: The method, apparatus, or non-transitory computer-readable medium of aspect 15, further including operations, features, circuitry, logic, means, or instructions, or any combination thereof for receiving a command to terminate the read error handling procedure based at least in part on identifying the one or more errors in the data, where ceasing to perform the second operation is based at least in part on receiving the command.

Aspect 17: The method, apparatus, or non-transitory computer-readable medium of any of aspects 13 through 16, where the first operation includes a first read operation for the data and a first error correction operation for the data and the second operation includes a second read operation for the data stored in the memory cells and a second error correction operation for the data.

Aspect 18: The method, apparatus, or non-transitory computer-readable medium of aspect 17, where transferring the data from a non-volatile memory array of a memory system to a controller of the memory system based at least in part on performing the first read operation, where the first error correction operation is performed at the controller based at least in part on transferring the data.

Aspect 19: The method, apparatus, or non-transitory computer-readable medium of any of aspects 17 through 18, where performing the first read operation includes reading one or more first pages of a non-volatile memory array, and performing the second read operation includes reading one or more second pages at a different level of the non-volatile memory array.

Aspect 20: The method, apparatus, or non-transitory computer-readable medium of aspect 19, where the one or more first pages and the one or more second pages are associated with single-level cells, multi-level cells, triple-level cells, quad-level cells, or penta-level cells.

Aspect 21: The method, apparatus, or non-transitory computer-readable medium of any of aspects 13 through 20, where the second operation is performed after the first operation based at least in part on the first operation being associated with lower latency or more simplicity than the second operation.

Aspect 22: The method, apparatus, or non-transitory computer-readable medium of any of aspects 13 through 21, further including operations, features, circuitry, logic, means, or instructions, or any combination thereof for performing a second channel activation operation to reduce residual charge on a second channel; performing a third operation as part of a second read error handling procedure; performing a fourth operation as part of the second read error handling procedure at least partially concurrently with performing the third operation; performing a fifth operation as part of the second read error handling procedure at least partially concurrently with performing the fourth operation; terminating the second read error handling procedure based at least in part on identifying one or more second errors in second data stored in second memory cells associated with the second channel during performing the fifth operation; and performing a second channel deactivation operation to reduce the residual charge on the second channel based at least in part on terminating the second read error handling procedure.

Aspect 23: The method, apparatus, or non-transitory computer-readable medium of any of aspects 13 through 22, further including operations, features, circuitry, logic, means, or instructions, or any combination thereof for performing a read operation; determining whether a rate of errors or a quantity of errors satisfies a threshold; and initiating the read error handling procedure based at least in part on determining that the rate of errors or the quantity of errors satisfies the threshold, where performing the first operation is based at least in part on initiating the read error handling procedure.

Aspect 24: The method, apparatus, or non-transitory computer-readable medium of aspect 23, further including operations, features, circuitry, logic, means, or instructions, or any combination thereof for receiving a plurality of operation commands based at least in part on initiating the read error handling procedure, where the plurality of operation commands include at least a first command for the first operation and a second command for the second operation.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
at least one non-volatile memory array; and
at least one controller coupled with the at least one non-volatile memory array and configured to cause the memory system to:
perform a first read operation as part of a read error handling procedure of the memory system;
perform an error correction operation on data associated with the first read operation based at least in part on performing the first read operation;
perform a second read operation as part of the read error handling procedure based at least in part on performing the first read operation, wherein the second read operation is initiated before the error correction operation is complete; and
terminate the read error handling procedure based at least in part on identifying that the error correction operation successfully corrected one or more errors in the data after initiating the performance of the second read operation.

2. The memory system of claim 1, wherein the at least one controller is further configured to cause the memory system to:
perform a channel activation operation to reduce residual charge on a channel of the memory system associated with the read error handling procedure, wherein performing the first read operation is based at least in part on performing the channel activation operation; and
perform a channel deactivation operation to reduce the residual charge on the channel based at least in part on terminating the read error handling procedure.

3. The memory system of claim 1, wherein the at least one controller is further configured to cause the memory system to:
receive a first command for the first read operation, wherein performing the first read operation is based at least in part on receiving the first command; and
receive a second command for the second read operation, wherein performing the second read operation is based at least in part on receiving the second command concurrently with performing the first read operation or the error correction operation.

4. The memory system of claim 1, wherein terminating the read error handling procedure is configured to cause the memory system to:
cease to perform the second read operation before completing the second read operation.

5. The memory system of claim 4, wherein the at least one controller is further configured to cause the memory system to:
receive a command to terminate the read error handling procedure based at least in part on identifying that the error correction operation successfully corrected the one or more errors in the data, wherein ceasing to perform the second read operation is based at least in part on receiving the command.

6. The memory system of claim 1, wherein the at least one controller is further configured to cause the memory system to:
transfer the data from the at least one non-volatile memory array to the at least one controller based at least in part on performing the first read operation, wherein the error correction operation is performed at the at least one controller based at least in part on transferring the data.

7. The memory system of claim 1, wherein the second read operation is performed after the first read operation based at least in part on the first read operation being associated with lower latency or more simplicity than the second read operation.

8. The memory system of claim 1, wherein performing the first read operation is configured to cause the memory system to:
read one or more first pages of the at least one non-volatile memory array, and performing the second read operation comprises reading one or more second pages at a different level of the at least one non-volatile memory array.

9. The memory system of claim 8, wherein:
the one or more first pages and the one or more second pages are associated with single-level cells, multi-level cells, triple-level cells, quad-level cells, or penta-level cells.

10. The memory system of claim 1, wherein the at least one controller is further configured to cause the memory system to:
perform a third read operation as part of a second read error handling procedure of the memory system;
perform a second error correction operation on second data associated with the third read operation based at least in part on performing the third read operation;
perform a fourth read operation as part of the second read error handling procedure based at least in part on performing the third read operation, wherein the fourth read operation is initiated before the second error correction operation is complete;
perform a third error correction operation on third data associated with the fourth read operation based at least in part on performing the fourth read operation;
perform a fifth read operation as part of the second read error handling procedure based at least in part on performing the fourth read operation, wherein the fifth read operation is initiated before the third error correction operation is complete; and
terminate the second read error handling procedure based at least in part on identifying that the third error correction operation successfully corrected one or more errors in the third data after initiating the performance of the fifth read operation.

11. The memory system of claim 1, wherein the at least one controller is further configured to cause the memory system to:
perform a third read operation;
determine whether a rate of errors or a quantity of errors satisfies a threshold; and
initiate the read error handling procedure based at least in part on determining that the rate of errors or the quantity of errors satisfies the threshold, wherein the performing of the first read operation is based at least in part on initiating the read error handling procedure.

12. The memory system of claim 11, wherein the at least one controller is further configured to cause the memory system to:
receive a plurality of operation commands based at least in part on initiating the read error handling procedure, wherein the plurality of operation commands include at least a first command for the first read operation and a second command for the second read operation.

13. A memory system, comprising:
at least one non-volatile memory array; and
at least one controller coupled with the at least one non-volatile memory array and configured to cause the memory system to:
perform a channel activation operation to reduce residual charge on a channel of the memory system;
perform a first operation as part of a read error handling procedure;
perform a second operation as part of the read error handling procedure at least partially concurrently with performing the first operation;
terminate the read error handling procedure based at least in part on identifying one or more errors in data stored in memory cells of the at least one non-volatile memory array associated with the channel during performing the second operation; and
perform a channel deactivation operation to reduce the residual charge on the channel based at least in part on terminating the read error handling procedure.

14. The memory system of claim 13, wherein the at least one controller is further configured to cause the memory system to:
receive a first command for the first operation, wherein performing the first operation is based at least in part on receiving the first command; and
receive a second command for the second operation, wherein performing the second operation is based at least in part on receiving the second command concurrently with performing the first operation.

15. The memory system of claim 13, wherein terminating the read error handling procedure is configured to cause the memory system to:
cease to perform the second operation before completing the second operation.

16. The memory system of claim 15, wherein the at least one controller is further configured to cause the memory system to:
receive a command to terminate the read error handling procedure based at least in part on identifying the one or more errors in the data, wherein ceasing to perform the second operation is based at least in part on receiving the command.

17. The memory system of claim 13, wherein:
the first operation comprises a first read operation for the data and a first error correction operation for the data, and
the second operation comprises a second read operation for the data stored in the memory cells and a second error correction operation for the data.

18. The memory system of claim 17, wherein the at least one controller is further configured to cause the memory system to:
transfer the data from the at least one non-volatile memory array to the at least one controller based at least in part on performing the first read operation, wherein an error correction operation to identify the one or more errors is performed at the at least one controller based at least in part on transferring the data.

19. The memory system of claim 17, wherein performing the first read operation is configured to cause the memory system to:
read one or more first pages of the at least one non-volatile memory array, and performing the second read operation comprises reading one or more second pages at a different level of the at least one non-volatile memory array.

20. The memory system of claim 19, wherein:
the one or more first pages and the one or more second pages are associated with single-level cells, multi-level cells, triple-level cells, quad-level cells, or penta-level cells.

21. The memory system of claim 13, wherein the second operation is performed after the first operation based at least in part on the first operation being associated with lower latency or more simplicity than the second operation.

22. The memory system of claim 13, wherein the at least one controller is further configured to cause the memory system to:
perform a second channel activation operation to reduce residual charge on a second channel of the memory system;
perform a third operation as part of a second read error handling procedure;
perform a fourth operation as part of the second read error handling procedure at least partially concurrently with performing the third operation;
perform a fifth operation as part of the second read error handling procedure at least partially concurrently with performing the fourth operation;
terminate the second read error handling procedure based at least in part on identifying one or more second errors in second data stored in second memory cells of the at least one non-volatile memory array associated with the second channel during performing the fifth operation; and
perform a second channel deactivation operation to reduce the residual charge on the second channel based at least in part on terminating the second read error handling procedure.

23. The memory system of claim 13, wherein the at least one controller is further configured to cause the memory system to:
perform a read operation;
determine whether a rate of errors or a quantity of errors satisfies a threshold; and
initiate the read error handling procedure based at least in part on determining that the rate of errors or the quantity of errors satisfies the threshold, wherein performing the first operation is based at least in part on initiating the read error handling procedure.

24. The memory system of claim 23, wherein the at least one controller is further configured to cause the memory system to:
receive a plurality of operation commands based at least in part on initiating the read error handling procedure, wherein the plurality of operation commands include at least a first command for the first operation and a second command for the second operation.
